(19) United States
(12) Patent Application Publication
(10) Pub. No.: US 2026/0165199 A1
(43) Pub. Date: Jun. 11, 2026

(54) SEMICONDUCTOR PACKAGE AND METHOD OF FORMING SAME

(71) Applicant: Taiwan Semiconductor Manufacturing Co., Ltd., Hsinchu (TW)

(72) Inventors: Tsung-Yang Peng, Pingtung (TW); Chin-Fu Kao, Taipei (TW); Amram Eitan, Hsinchu County (TW); Kai-Hsiang Yang, Hsinchu County (TW); Yen-Chia Liu, Tainan (TW)

(21) Appl. No.: 18/972,541

(22) Filed: Dec. 6, 2024

(51) Int. Cl. H01L 23/00; H01L 25/065

(52) U.S. Cl. CPC H10W 90/00; H10W 72/953; H10W 80/102; H10W 80/327; H10W 90/20

(57) ABSTRACT

In an embodiment, a method that includes forming a first semiconductor structure including a first plurality of metal lines in a first dielectric stack; wherein a first upper layer of the first dielectric stack includes an inorganic bonding layer and a first copper containing contact pad to the first plurality of metal lines; and forming a second semiconductor structure including a second plurality of metal lines in a second dielectric stack, wherein a second upper layer of the second dielectric stack includes an organic bonding layer and a second copper containing contact pad. The method may further include contacting the first upper layer to the second upper layer with the first copper containing contact pad aligned to the second copper containing contact pad; and bonding the first semiconductor structure to the second semiconductor structure. In some embodiments, the inorganic bonding layer is bonded to the organic bonding layer.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4 illustrate side cross-sectional views of hybrid bonding as used in packaging of electronic devices, in which the hybrid bonding dielectrics include a silicon containing inorganic bonding layer and an organic bonding layer, in accordance with some embodiments.

FIG. 5 illustrates an embodiment of a chemical formula illustrating bonding of the inorganic bonding layer of the first semiconductor structure to the organic bonding layer of the second semiconductor structure, in accordance with some embodiments.

FIGS. 6A and 6B are side cross-sectional view of the hybrid bonding as used in packaging of electronic devices, in which the hybrid bonding dielectrics absorb defects without forming voids at the bonding interface, in accordance with some embodiments.

FIGS. 7-10 illustrate side cross-sectional views of fusion bonding as used in packaging of electronic devices, in which the fusion bonding dielectrics include a silicon containing inorganic bonding layer and an organic bonding layer, in accordance with some embodiments.

FIGS. 11-14 illustrate side cross-sectional views of hybrid bonding as used in packaging of electronic devices in combination with gap fill materials, in which the hybrid bonding dielectrics include a silicon containing inorganic bonding layer and an organic bonding layer, in accordance with some embodiments.

FIG. 15 illustrates a side cross-sectional view of an electronics package that was formed using a hybrid dielectric bonding method, in which the polymeric bonding layer is integrated into the top side of the package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a method is described for packaging electronics, such as those including 2.5D (two-and-a-half dimensional) integrated circuit, and 3D (three dimensional) integrated circuits, e.g., system on chip (SoC) and/or system on integrated circuit (SoIC), using bonding techniques that rely upon metal-to-metal bonding in combination with dielectric-to dielectric bonding and/or bonding techniques the rely solely upon dielectric-to-dielectric bonding. Hybrid/fusion bond techniques can be sensitive to the surface cleanliness, especially the presence of residue particles. For example, in some instances, during the bonding layer process flow used in electronic packaging a small particle can cause the formation of a void post bond. In some applications, any particles, contamination, or poor flatness can lead to poor bonding performance. In the methods and structures described herein, the dielectric film pair for bonding includes a silicon base dielectric layer (“an inorganic bonding layer”) and non-silicon base dielectric layer (“an organic bonding layer”). In some embodiments, the transformation and deformation in the non-silicon base dielectric material can wrap around particles or roughness during bonding, which can reduce void trapping for better joint yield.

In an embodiment, the packaging method can include forming a first semiconductor structure and a second semiconductor structure for bonding to one another. The first semiconductor structure can include a first plurality of metal lines in a first dielectric stack over a first substrate, wherein a first upper layer of the first dielectric stack includes an inorganic bonding layer and a first copper containing contact pad to the first plurality of metal lines. The second semiconductor structure can include a second plurality of metal lines in a second dielectric stack over a second substrate, wherein a second upper layer of the second dielectric stack includes an organic bonding layer and a second copper containing contact pad. Bonding the first semiconductor structure to the second semiconductor structure can include contacting the first upper layer to the second upper layer with the first copper containing contact pad aligned to the second copper containing contact pad. The first semiconductor structure is bonded to the second semiconductor structure, wherein the inorganic bonding layer is bonded to the organic bonding layer and the first copper containing contact pad is bonded to the second copper containing contact pad.

Embodiments are described below in a particular context, e.g., using hybrid bonding in packaging of electronic devices that can include FETs, such as nano-FETs.

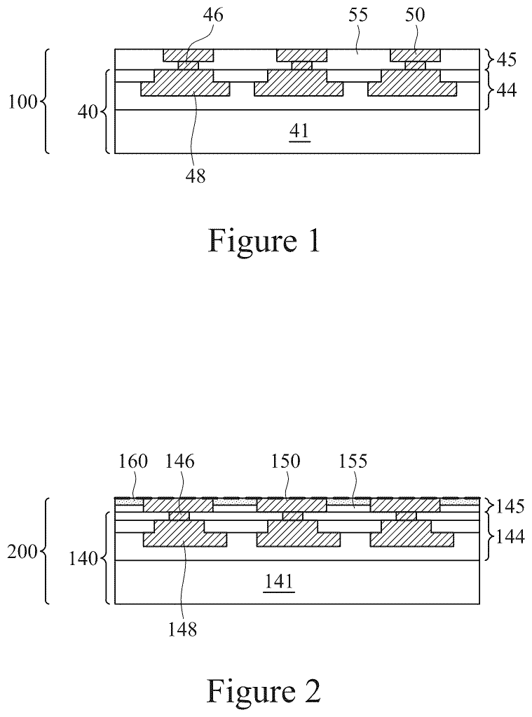

FIG. 1 illustrates an example of a first semiconductor structure 100. In some embodiments, the first semiconductor structure 100 includes a first package component 40. In accordance with some embodiments, first package components 40 are individual device dies, packages having one or more device dies packaged therein, System-on-Chip (SoC) dies including a plurality of integrated circuits (or device dies) integrated as a system, or the like. The device die(s) in first package components 40 may be or may comprise logic dies, memory dies, input-output dies, Integrated Passive Devices (IPDs), the like, or combinations thereof. For example, the logic device die(s) in first package components 40 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory die(s) in first package components 40 may include Static Random Access Memory (SRAM) dies, Dynamic Random Access Memory (DRAM) dies, or the like. The device die(s) in first package components 40 may include semiconductor substrates and interconnect structures.

In accordance with some embodiments, first package component 40 may include a first substrate 41 comprising a semiconductor substrate (e.g., a silicon substrate), integrated circuit devices (not separately illustrated) at a front-side surface of first substrate 41, a plurality of first dielectric layers 44 formed over the first substrate 41 and the integrated circuit devices. The integrated circuit devices may include active devices, passive devices, and the like. A plurality of first conductive vias 46 and a first plurality of metal lines 48 may be present in the plurality of first dielectric layers 44. In some embodiments, the first substrate 41 may provide a top die component in the final electronics package.

The plurality of first dielectric layers 44 may be selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). Additional choices for the interlevel dielectric layer include any of the aforementioned materials in porous form, or in a form that changes during processing to or from being porous and/or permeable to being non-porous and/or non-permeable. The deposited dielectric is then patterned and etched to form trenches for the first plurality of metal lines 48, e.g., interconnect lines, and via holes for the first conductive vias 46. Following via formation interconnects are formed by depositing a conductive metal into the via holes using deposition methods, such as CVD, PVD or plating.

In some embodiments, the first conductive vias 46 may extend through one or more of first dielectric layers 44, and may extend either partially or entirely through the one or more first dielectric layers 44. In some embodiments, the first plurality of metal lines 48 is disposed over the front-side of the first substrate 42 and embedded in plurality of first dielectric layers 44. In some embodiments, the first plurality of metal lines 48 includes metal lines and vias electrically connected to the integrated circuit devices. In some embodiments, the first plurality of metal lines 48 includes a plurality of levels of the metal lines, wherein one or more levels of upper metal lines of the first plurality of metal lines 48 may be coupled with corresponding ones of first conductive vias 46. The first plurality of metal lines 48 and/or the through conductive vias 46 may be composed of a metal, such as copper (Cu), aluminum (Al), titanium (Ti), tantalum (Ta), tungsten (W), platinum (Pl), gold (Au), silver (Ag) and combinations thereof.

In some embodiments, the first semiconductor structure 100 also includes a first bonding level 45. The first bonding level 45 may include first bonding pads 50 electrically connected to upper metal lines of the first plurality of metal lines 48 by conductive vias. The first bonding pads 50 may be composed of a metal, such as copper (Cu), or the like. Copper (Cu) may be employed in the first bonding pads 50 when the bonding method includes copper-to-copper bonding for semiconductor packaging. The copper-to-copper bonding method involves directly bonding copper connections between stacked dies, which allows for higher density and improved performance compared to methods like microbumps and pillars. As will be further described below, the copper-to-copper hybrid bonding method can include preparing the surfaces of the copper pads on each die are prepared and cleaned to ensure a strong bond; and aligning the dies so that the copper pads (also referred to as first bonding pads 50) on each die (first semiconductor structure 100 and the second semiconductor structure 200) match up perfectly. In a following process sequence, the copper-to-copper hybrid bonding method involves the dies (first semiconductor structure 100 and second semiconductor structure 200) being pressed together, and the copper pads (first bonding pads 50 and second bonding pads 150) bond through a process of diffusion, creating a direct electrical connection.

In some embodiments, the first bonding pads 50 are present in an inorganic bonding layer 55 of the first bonding level 45. The inorganic bonding layer 55 may be a silicon containing bonding layer. For example, the inorganic bonding layer 55 may include silicon oxide (SiOx), phospho-silicate glass (PSG), borosilicate glass (BSG), boron-doped phospho silicate glass (BPSG), fluorine-doped silicate glass (FSG), silicon nitride (SixNy), silicon oxynitride (SiON), silicon oxycarbide (SiOC), silicon carbonitride (SiCN), or combinations thereof.

In some embodiments, the first bonding level 45 may be formed by first depositing the material layers for the inorganic bonding layer 55. In some embodiments, the inorganic bonding layer 55 may be deposited by one of spin coating, Flowable Chemical Vapor Deposition (FCVD), Plasma Enhanced Chemical Vapor Deposition (PECVD), Low Pressure Chemical Vapor Deposition (LPCVD), Atomic Layer Deposition (ALD), the like, or combinations thereof.

The first bonding pads 50 may then be formed in the inorganic bonding layer 55. For example, openings are formed in the inorganic bonding layer 55 by first applying a photoresist over a top surface of the inorganic bonding layer 55 and then patterning the photoresist using a photolithographic mask. The patterned photoresist is then developed and used as an etching mask to etch openings in the inorganic bonding layer 55. To form the openings, the inorganic bonding layer 55 may be etched by a suitable process, such as dry etching (e.g., reactive ion etching (RIE) or neutral beam etching (NBE), etc.), wet etching, or the like. The openings are aligned to the first conductive vias 46, so that the first bonding pads 50 that are formed in the openings are in direct contact with the first conductive vias 46. In some embodiments, the pattern and etch process for forming a photolithographic mask may employ a dual damascene method.

The openings within the inorganic bonding layer 55 may then be filled with a conductive material to form the first bonding pads 50. In an embodiment, the conductive material may comprise a seed layer and a plate metal (not separately illustrated). The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, aluminum, an aluminum-copper alloy, or the like. In some embodiments, the deposited material for the first bonding pads 50 may be planarized, for example, using a chemical mechanical polish (CMP) or a grinding process. The remaining portions of the conductive material (e.g., the seed layer and the plate metal) form the first bonding pads 50.

It is noted that the above description of forming the first package component 40 is provided for illustrative purposes, and may further include additional intermediate steps not specifically depicted. For example, one or more carrier substrates may be employed in forming the structure depicted in FIG. 1. The carrier substrates may include a base carrier and one or more dielectric bond layers. In some embodiments, base carrier may be a wafer, and may be formed of a same material as semiconductor substrate in the overlying first package component 40, so that in the subsequent packaging process, warpage caused by mismatch of Coefficients of Thermal Expansion (CTE) is reduced. For example, base carrier may be formed of or comprise silicon, while other materials such as laminate, ceramic, glass, silicate glass, or the like, may also be used.

The carrier substrate may be employed to support the first package component 40 during manufacturing. More specifically, in some embodiments, the carrier substrate supports the first package component from the opposite side from which the processing is being performed. In some embodiments, at least one carrier substrate can support the first package component 40 until the first package component is bonded to the second package component, as described in FIG. 4.

In some embodiments, when employing a carrier substrate, before attaching first package components 40 to the carrier substrate, dielectric bond layers can be deposited on base carrier. The dielectric bond layers are used to temporarily and/or reversibly attach the carrier substrate to the first package components. In some embodiments, the dielectric bond layers may include oxide based materials (which may also be silicon oxide based) such as silicon oxide (SiOₓ), phospho-silicate glass (PSG), borosilicate glass (BSG), boron-doped phospho silicate glass (BPSG), fluorine-doped silicate glass (FSG), nitride-based materials such as silicon nitride (SiₓN_{y}), oxynitride based materials such as silicon oxynitride (SiON), while it may also be formed of or comprises other materials such as silicon oxycarbide (SiOC), silicon carbonitride (SiCN), or the like. Dielectric bond layers may be formed using spin coating, FCVD, Plasma Enhanced Chemical Vapor Deposition (PECVD), Low Pressure Chemical Vapor Deposition (LPCVD), Atomic Layer Deposition (ALD), the like, or combinations thereof. Typically, after the stage of processing is completed that the carrier substrate is used to support the first semiconductor structure 100, the carrier substrate may be released by removing the bonding force of the dielectric bond layer.

FIG. 2 illustrates an example of a second semiconductor structure 200. In some embodiments, the second semiconductor structure 200 includes a second package component 140. In accordance with some embodiments, the second package components 140 are individual device dies, packages having one or more device dies packaged therein, System-on-Chip (SoC) dies including a plurality of integrated circuits (or device dies) integrated as a system, or the like. The device die(s) in the second package components 140 may be or may comprise logic dies, memory dies, input-output dies, Integrated Passive Devices (IPDs), the like, or combinations thereof. For example, the logic device die(s) in the second package components 140 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory die(s) in the second package components 140 may include Static Random Access Memory (SRAM) dies, Dynamic Random Access Memory (DRAM) dies, or the like. The device die(s) in the second package components 140 may include semiconductor substrates and interconnect structures.

In accordance with some embodiments, the second package components 140 may include a second substrate 141 comprising a semiconductor substrate (e.g., a silicon substrate), integrated circuit devices (not separately illustrated) at a front-side surface of the second substrate 141, a plurality of second dielectric layers 144 formed over the second substrate 141 and the integrated circuit devices. The integrated circuit devices may include active devices, passive devices, and the like. A plurality of second conductive vias 146 and a second plurality of metal lines 148 may be present in the plurality of second dielectric layers 144. In some embodiments, the second substrate 141 may provide a packaging substrate, support substrate and/or carrier substrate in the final device package.

The plurality of second dielectric layers 144 may be selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). Additional choices for the interlevel dielectric layer include any of the aforementioned materials in porous form, or in a form that changes during processing to or from being porous and/or permeable to being non-porous and/or non-permeable. The deposited dielectric is then patterned and etched to form trenches for the second plurality of metal lines 148, e.g., metal lines, and via holes for the second conductive vias 146. Following via formation interconnects are formed by depositing a conductive metal into the via holes using deposition methods, such as CVD, PVD or plating.

In some embodiments, the second conductive vias 146 may extend through one or more of second dielectric layers 144, and may extend either partially or entirely through the one or more second dielectric layers 144. In some embodiments, the plurality of second metal lines 148 is disposed over the front-side of the second substrate 142 and embedded in plurality of second dielectric layers 144. The plurality of second metal lines 148 includes metal lines and vias electrically connected to the integrated circuit devices. In some embodiments, the second plurality of metal lines 148 include a plurality of levels of the metal lines, wherein one or more levels of upper metal lines may be coupled with corresponding ones of first conductive vias 146. The plurality of second metal lines 148 and/or the second through conductive vias 146 may be composed of a metal, such as copper (Cu), aluminum (Al), titanium (Ti), tantalum (Ta), tungsten (W), platinum (Pl), gold (Au), silver (Ag) and combinations thereof.

In some embodiments, the second semiconductor structure 200 also includes a second bonding level 145. The second bonding level 145 may include second bonding pads 150 electrically connected to upper metal lines of plurality of second metal lines 148 by conductive vias. The second bonding pads 150 may be composed of copper (Cu). Copper (Cu) may be employed in the second bonding pads 150 when the bonding method includes copper-to-copper hybrid bonding for semiconductor packaging.

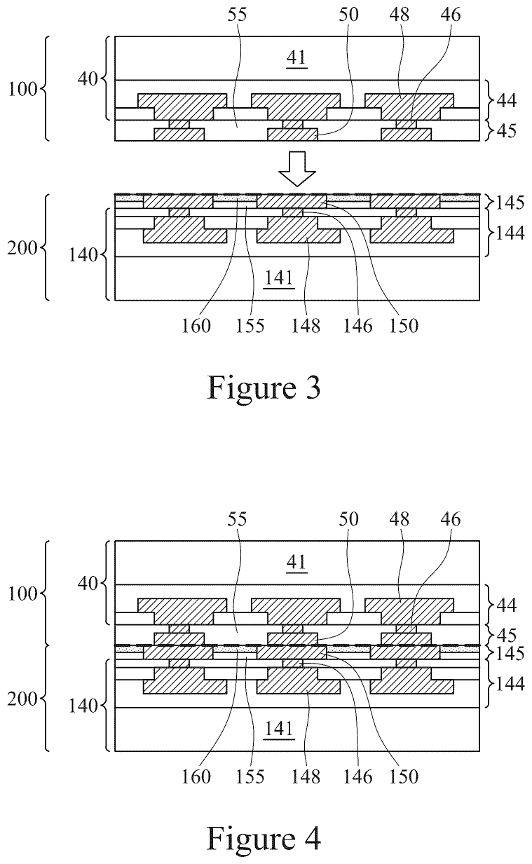

In some embodiments, the second bonding pads 150 are present in an organic bonding layer 160 of a second bonding level 145. In some embodiments, the organic bonding layer 160 may be a polymeric bonding layer. In some embodiments, the organic bonding layer 160 may include carbon in amounts ranging from 40 wt. % to 90 wt. %. For example, the organic bonding layer 160 may include epoxy resins, polyimides, acrylics, silicones, benzocyclobutene (BCB), polymethylmethacrylate (PMMA), polystyrene (PS), or combinations thereof. In some embodiments, the thickness of the organic bonding layer 160 is less than the thickness of the second bonding pads 150. For example, the organic bonding layer 160 can have a thickness that is less than 1/2 the thickness of the second bonding pad 150, which may be a copper bonding pad. In some embodiments, the aforementioned conditions for the thickness for the organic bonding layer 160 can facilitate copper to copper bonding, as described below with reference to FIGS. 3 and 4. For example, the organic bonding layer 160 may have a thickness ranging from 10 nm to 5000 nm. For example, the second bonding pad 150 may have a thickness ranging from 100 nm to 10,000 nm. Here the maximum thickness of organic bonding layer 160 would be the half thickness of the second bonding pad 150. For example, if the thickness of second bonding pad 150 had been defined to 1000 nm, the variable thickness of organic bonding layer 160 would be from 10 nm to 500 nm.

Referring to FIG. 2, in some embodiments, the organic bonding layer 160 is separated from the plurality of second dielectric layers 144 by an intermediate inorganic bonding layer 155. The intermediate inorganic bonding layer 155 may be a silicon containing bonding layer. For example, the intermediate inorganic bonding layer 155 may include silicon oxide (SiOₓ), phospho-silicate glass (PSG), borosilicate glass (BSG), boron-doped phospho silicate glass (BPSG), fluorine-doped silicate glass (FSG), silicon nitride (SiₓN_{y}), silicon oxynitride (SiON), silicon oxycarbide (SiOC), silicon carbonitride (SiCN), or combinations thereof. In some embodiments, the thickness of the intermediate inorganic bonding layer 155 may provide that the intermediate of the second bonding pad 150 is coplanar with the intermediate of the intermediate inorganic bonding layer 155. For example, the intermediate inorganic bonding layer 155 may have a thickness ranging from 50 nm to 5000 nm. The thickness of the second bonding pad 150 is equal to the total thickness of the intermediate inorganic layer 155 and the organic bonding layer 160. Because the CTE of metal materials (ex, copper) is larger than that of dielectric materials. Therefore, the thickness of organic bonding layer was constrained to half of the second bonding pad. If the thickness of organic bonding layer was larger to half of the second bonding pad, the extension amount of organic layer would be larger than that of the second bonding pad. That resulted in poor contact of Cu to Cu pad which gave a open in electrical circuit situation.

In some embodiments, the second bonding level 145 may be formed by first depositing the material layers for the intermediate inorganic bonding layer 155 and the organic bonding layer 160. In some embodiments, each of the intermediate inorganic bonding layer 155 and the organic bonding layer 160 are deposited by one of spin coating, Flowable Chemical Vapor Deposition (FCVD), Plasma Enhanced Chemical Vapor Deposition (PECVD), Low Pressure Chemical Vapor Deposition (LPCVD), Atomic Layer Deposition (ALD), the like, or combinations thereof.

The second bonding pads 150 may then be formed in the organic bonding layer 160 and the intermediate inorganic bonding layer 155. For example, openings are formed in the organic bonding layer 160 and the intermediate inorganic bonding layer 155 by first applying a photoresist over a top surface of the organic bonding layer 160 and patterned using a photolithographic mask. The patterned photoresist is then used as an etching mask to etch openings in the organic bonding layer 160 and the intermediate inorganic bonding layer 155. To form the openings, the organic bonding layer 160 and the intermediate inorganic bonding layer 155 may be etched by a suitable process, such as dry etching (e.g., reactive ion etching (RIE) or neutral beam etching (NBE), etc.), wet etching, or the like. The openings are aligned to the conductive vias 146, so that the second bonding pads 150 that are formed in the openings are in direct contact with the second conductive vias 146.

The openings within the organic bonding layer 160 and the intermediate inorganic bonding layer 155 may then be filled with a conductive material to form the second bonding pads 150. In an embodiment, the conductive material may comprise a seed layer and a plate metal (not separately illustrated). The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, aluminum, an aluminum-copper alloy, or the like. In some embodiments, the deposited material for the second bonding pads 150 may be planarized, for example, using a chemical mechanical polish (CMP) or a grinding process. The remaining portions of the conductive material (e.g., the seed layer and the plate metal) form the second bonding pads 150.

It is noted that the above description of forming the second semiconductor structure 200 is provided for illustrative purposes, and may further include additional intermediate steps not specifically depicted. For example, one or more carrier substrates may be employed in forming the structure depicted in FIG. 2. The carrier substrates may include a base carrier and one or more dielectric bond layers. In some embodiments, base carrier may be a wafer, and may be formed of a same material as semiconductor substrate in the overlying second semiconductor structure 200, so that in the subsequent packaging process, warpage caused by mismatch of Coefficients of Thermal Expansion (CTE) is reduced. For example, base carrier may be formed of or comprise silicon, while other materials such as laminate, ceramic, glass, silicate glass, or the like, may also be used.

The carrier substrate may be employed to support the second semiconductor structure 200 during manufacturing. More specifically, in some embodiments, the carrier substrate supports the first package component from the opposite side from which the processing is being performed. In some embodiments, at least one carrier substrate can support the second semiconductor structure 200 until the second semiconductor structure is bonded to the first semiconductor structure 100, as described in FIG. 4. Further details for the base carrier and the one or more dielectric bond layers are provided above where the use of the carrier substrates is described for supporting the first semiconductor structure 100.

FIG. 3 illustrates an embodiment of aligning the first bonding pads 50 to the second bonding pads 150 in preparation for hybrid bonding, e.g., copper to copper hybrid bonding that incorporates bonding through the inorganic bonding layer 55 and the organic bonding layer 160. In accordance with some embodiments, the bonding of first semiconductor structure 100 to the second semiconductor structure 200 includes pre-treating the inorganic bonding layer 55 and the organic bonding layer 160 in a process gas comprising oxygen (O₂) and/or nitrogen (N₂), performing a pre-bonding process to join inorganic bonding layer 55 and organic bonding layer 160 together, and performing an annealing process following the pre-bonding process. In accordance with some embodiments, during the pre-bonding process, first semiconductor structure 100 are put into contact with second semiconductor structure 200, with a pressing force applied to press the first bonding pads 50 in direct contact with the second bonding pads 150, and with the pressing force applied to press the inorganic bonding layer 55 to the organic bonding layer 160. The pre-bonding may be performed at room temperature (in a range from 20° C. to 25° C.) with a low bonding force (in a range from 0.1 kgf to 5 kgf), and a higher temperature may also be used. In some embodiments, the pre-bonding process includes a plasma treatment and/or wet-clean as a hydration step. In some examples, the plasma treatment can employ a capacitively coupled plasma (CCP), inductively coupled plasma (ICP) or remote plasma sources (RPS) chamber consisting of RF power sources of 13.56 MHz and 40 kHz. In some embodiments, the plasma and/or wet-clean treatments may include generating hydroxyl groups (OH) on at least the faces of the inorganic bonding layer 55.

FIG. 4 illustrates an embodiment of contacting the upper layer of the first semiconductor structure 100 to the upper layer of the second semiconductor structure 200 with the first bonding pads 50, e.g., first copper containing contact pad, aligned to the second bonding pads 150, e.g., second copper containing contact pad; and bonding the first semiconductor structure 100 to the second semiconductor structure 200. In some embodiments, the inorganic bonding layer 55 is bonded to the organic bonding layer 160, and the first bonding pads 50 are bonded to the second bonding pads 150. After the pre-bonding as described above with reference to FIG. 3, an annealing process is performed. Chemical bonds, such as silicon to oxygen (Si—O) bonds and/or silicon to nitrogen (Si—N), may be formed between the inorganic bonding layers 55 and the organic bonding layers 160, so that the inorganic bonding layers 55 and organic bonding layers 160 are bonded to each other with high bonding strength. In accordance with some embodiments, the annealing process is performed at a temperature in a range from 200° C. to 400° C. The annealing duration may be in a range from 30 minutes to 60 minutes.

After the dielectric bonding that forms the bond between the inorganic bonding layers 55 and the organic bonding layers 160, a low-temperature annealing process (typically between 150° C. and 300° C.) is used to establish a metal-to-metal connection through bonding of the first bonding pads 50 to the second bonding pads 150, specifically copper-to-copper (Cu-to-Cu). In some examples, this step involves the solid-state diffusion of copper atoms, creating a robust and reliable bond. For copper-to-copper hybrid bonding, the preferred pressure may range from 100 MPa to 200 MPa. This high pressure can facilitate diffusion of copper atoms across the bonding interface, which can lead to creating a strong and reliable connection.

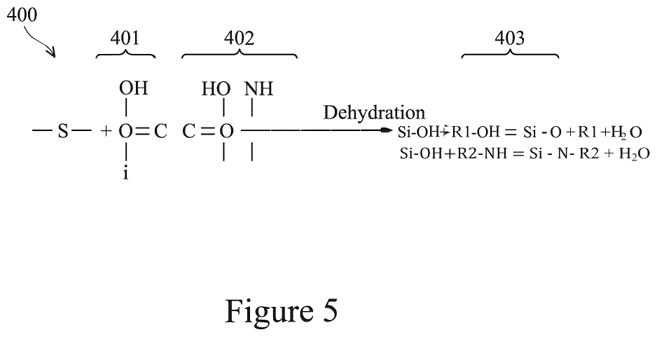

FIG. 5 illustrates an embodiment of a chemical formula 400 illustrating bonding of the inorganic bonding layer 55 of the first semiconductor structure 100 to the organic bonding layer 160 of the second semiconductor structure 200. In some embodiments, during the annealing process water (H₂O) is evaporated from the first and second semiconductor structures 100, 200 as part of a dehydration process, which can also remove hydroxide groups (OH) from the inorganic bonding layer 55 and/or the organic bonding layer 160. In some embodiments, silanol groups 401 from the inorganic bonding layer 55 and carboxylic groups 402 from the organic bonding layer 160 react to create silicon to oxygen (Si-O) bonds and silicon to nitrogen (Si-N) bonds 403 that provide the bonding between the inorganic bonding layer 55 of the first semiconductor structure 100, and the organic bonding layer 160 of the second semiconductor structure 200.

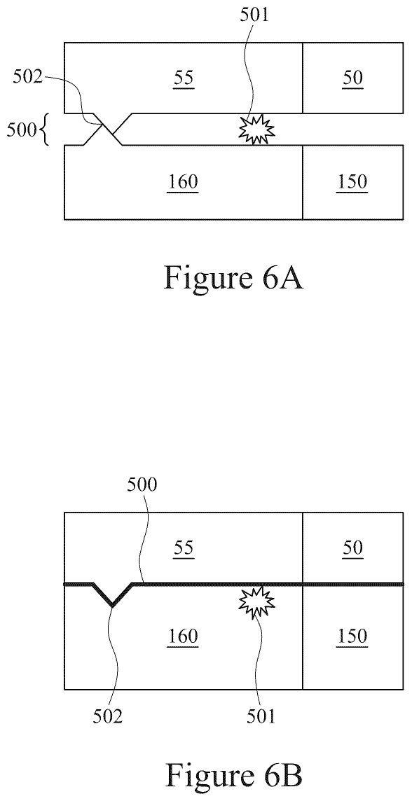

FIGS. 6A and 6B illustrate the hybrid bonding as used in packaging of electronic devices, in which the hybrid bonding dielectrics, e.g., the organic bonding layer 160, absorb defects, e.g., particle defects 501 and rough textures (surface roughness 502), without forming voids at the bonding interface. FIG. 6A illustrates a pre-bonding stage of the inorganic bonding layer 55 and the organic bonding layer 160. FIG. 6B illustrates bonding of the inorganic bonding layer 55 to the organic bonding layer 160, which would bond the first semiconductor structure 100 to the second semiconductor structure 200, as depicted in FIG. 4. The bonding interface is the contacting surfaces of the inorganic bonding layer 55 and the organic bonding layer 160. Preventing voids and areas of non-bonding is a concern of hybrid bonding technology. Particles, contamination, or poor flatness can lead to poor bonding performance of the inorganic bonding layer 55 and another inorganic bonding layer 55. In the methods and structures of the present disclosure, the dielectric film pair of an inorganic bonding layer 55 composed of a silicon base material and an organic bonding layer 160 of a non-silicon base dielectric material, can more readily absorb particle defects 501 and surface roughness 502 at the bond interface 500. For example, the transformation and deformation in the organic bonding layer 160, e.g., non-silicon base dielectric material, can wrap around particle defects 501 or surface roughness 502 during bonding, which reduces voids trapping and increases joint yield. In some embodiments, during the bonding and annealing processes, the temperature is raised above the glass transition temperature (Tg) of the polymer material of the organic bonding layer 160 to make it become softer and is able to wrap particle defects 501 and surface roughness 502 at the bond interface 500. For example, the particle defects 501 and surface roughness 502 is clearly illustrated as being absorbed by the organic bonding layer 160.

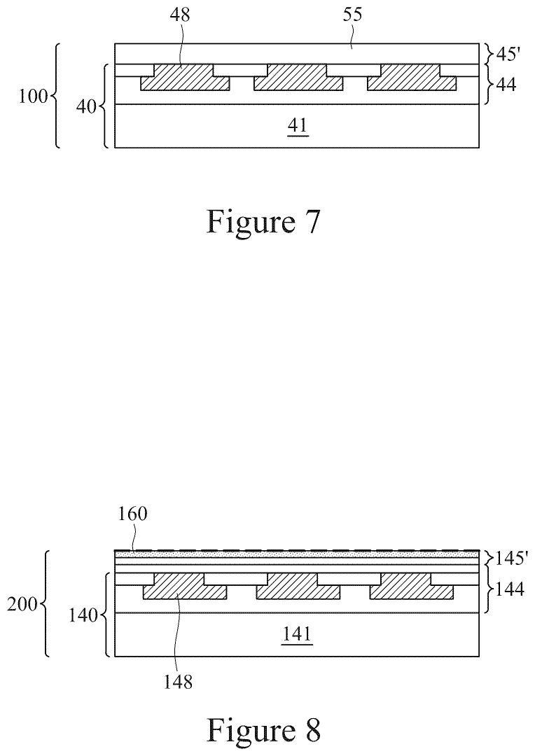

FIGS. 7-10 illustrate an embodiment of bonding as used in packaging of electronic devices that relies solely upon dielectric-to-dielectric bonding. In contrast to the bonding method described with reference to FIGS. 1-6, the bonding process depicted in FIGS. 7-10 does not include metal to metal, e.g., copper (Cu) to copper (Cu) bonding. In the embodiments depicted in FIGS. 7-10, the bonding dielectrics include an inorganic bonding layer 55 and an organic bonding layer 160. The methods and structures depicted in FIGS. 7-10 are similar to those described above with reference to FIGS. 1-4. However, because the method illustrated in FIGS. 1-4 is a bonding method that employs both metal to metal bonding and dielectric to dielectric bonding, the first bonding level 45 and second bonding level 145 for the first and second semiconductor structures 100, 200 depicted in FIGS. 1-4 include first and second bonding pads 50, 150 (e.g., the metal containing structures for the metal to metal bonding), whereas the method illustrated in FIGS. 7-10 is a bonding method in which the bonding levels 45′, 145′ for the first and second semiconductor structures 100, 200 depicted in FIGS. 7-10 do not include metal bonding pads. Elements in FIGS. 7-10 having the same reference numbers as elements depicted in FIGS. 1-4 may be described by the descriptions of those elements provided above in the description of FIGS. 1-4, as well as FIGS. 5-6B.

FIG. 7 illustrates an embodiment of a method that includes forming a first semiconductor structure 100 including a first plurality of metal lines 48 in the plurality of first dielectric layers 44 over a first substrate 41, wherein a first upper layer of the plurality of first dielectric layers 44 includes an inorganic bonding layer 55a. The inorganic bonding layer 55 may be composed of a silicon containing bonding layer. The inorganic bonding layer 55 may be silicon oxide (SiOₓ), phospho-silicate glass (PSG), borosilicate glass (BSG), boron-doped phospho silicate glass (BPSG), fluorine-doped silicate glass (FSG), silicon nitride (SiₓN_{y}), silicon oxynitride (SiON), silicon oxycarbide (SiOC), silicon carbonitride (SiCN), or combinations thereof.

FIG. 8 illustrates an embodiment of a method that includes forming a second semiconductor structure 200 including a second plurality of metal lines 148 in a plurality of second dielectric layers 144 over a second substrate 141, wherein a second upper layer of the plurality of second dielectric layers 144 includes an organic bonding layer 160. In some embodiments, the organic bonding layer 160 carbon in amounts ranging from 40 wt. % to 90 wt. %. In some embodiments, the organic bonding layer 160 includes epoxy resins, polyimides, acrylics, silicones, benzocyclobutene (BCB), polymethylmethacrylate (PMMA), polystyrene (PS), or combinations thereof. In some embodiments, the plurality of second dielectric layers 144 and the second plurality of metal lines 148 is separated from the organic bonding layer 160 by an intermediate inorganic bonding layer 155.

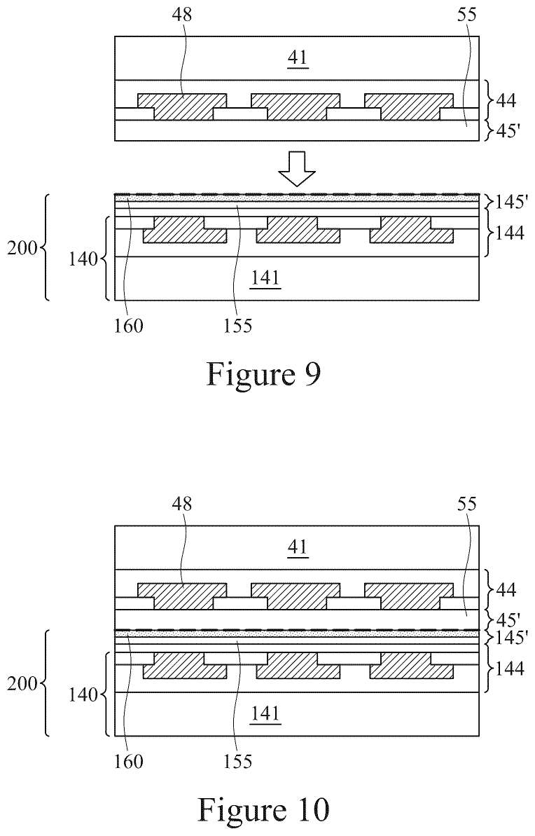

FIG. 9 illustrates an embodiment of flipping the first semiconductor structure 100 to provide that the inorganic bonding layer 55 faces and is aligning with the organic bonding layer 160 of the second semiconductor structure 200. In accordance with some embodiments, the bonding of first semiconductor structure 100 to the second semiconductor structure 200 includes pre-treating the inorganic bonding layer 55 and the organic bonding layer 160 in a process gas comprising oxygen (O₂) and/or nitrogen (N₂), performing a pre-bonding process, such as a plasma process that forms hydroxide groups on at least the inorganic bonding layer 55, to join inorganic bonding layer 55 and organic bonding layer 160 together. The pre-treatment may further include performing an annealing process following the pre-bonding process. Further details for the pretreatment (including the plasma process) are provided above with reference to FIG. 3.

FIG. 10 illustrates an embodiment of contacting the inorganic bonding layer 55 to the organic bonding layer 160, and bonding the first semiconductor structure 100 to the second semiconductor structure 200, wherein the inorganic bonding layer 55 is bonded to the organic bonding layer 160. In some embodiments, bonding is effectuated by an annealing process. In some embodiments, during annealing, chemical bonds, such as silicon to oxygen (Si—O) bonds and/or silicon to nitrogen(Si—N), may be formed between the inorganic bonding layers 55 and the organic bonding layers 160, so that the inorganic bonding layers 55 and organic bonding layers 160 are bonded to each other with high bonding strength. In some embodiments, during the bonding and annealing processes, the temperature is raised above the glass transition temperature (Tg) of the polymer material of the organic bonding layer 160 to make it become softer and more able to absorb particle defects 501 and surface roughness 502 at the bond interface 500 in a manner that avoids void formation. Further details for the bonding processes (including the annealing process) are provided above with reference to FIG. 4.

In some embodiments, the bonding method that is depicted in FIGS. 7-10 may be employed for bonding to carrier wafers, because the bonding levels 45′, 145′ of the bonding method does not include first and second bonding pads 50, 150.

In some embodiments, the methods and structures described with reference to FIGS. 1-10 may be suitable for wafer to wafer (W2W) and/or die to wafer (D2W) processing.

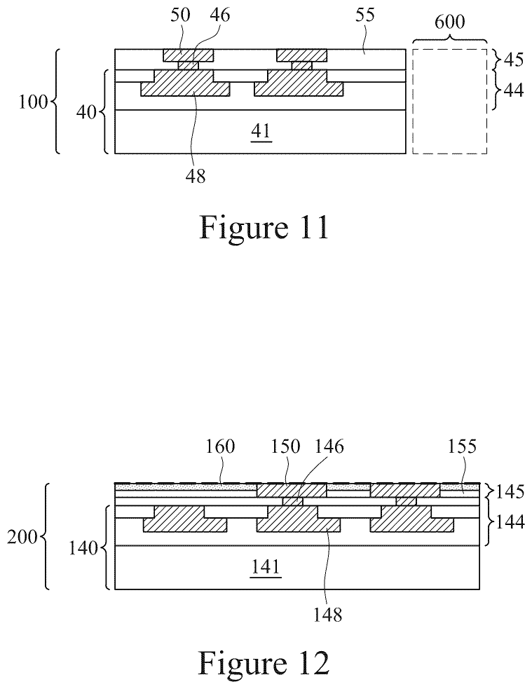

FIGS. 11-14 illustrate hybrid bonding as used in packaging of electronic devices in combination with gap fill materials, e.g., a gap fill 650, in which the hybrid bonding dielectrics include an inorganic bonding layer 55 and an organic bonding layer 160. The methods described with reference to FIGS. 11-14 may be used for process flows for producing system on chip (SoC) and/or system on integrated chip (SoIC) devices. For example, the when employed for system on chip (SoC) and/or system on integrated chip (SoIC), the first semiconductor structure 100 that is sectioned using singulation processes may be referred to as one or more die, and the second semiconductor structure 200 may be a substrate, e.g., carrier substrate.

The methods and structures depicted in FIGS. 11-14 are similar to those described above with reference to FIGS. 1-4. However, the method depicted in FIGS. 11-14 further includes process steps for singulation at FIG. 11, and forming a gap fill 650 at FIG. 14. Elements in FIGS. 11-14 having the same reference numbers as elements depicted in FIGS. 1-4 may be described by the descriptions of those elements provided above in the descriptions of FIGS. 1-4, as well as FIGS. 5-6B.

FIG. 11 illustrates one embodiment of forming a first semiconductor structure 100 including a first plurality of metal lines 48 in a plurality of first dielectric layers 44 over a first substrate 41, wherein a first upper layer of the plurality of first dielectric layers 44 includes an inorganic bonding layer 55 and a first bonding pad 50 to the first plurality of metal lines 48. As noted above, the inorganic bonding layer 55, as well as the other elements having references numbers depicted in FIG. 11 have been described above with reference to FIGS. 1-6B.

After forming the first semiconductor structure 100, the singulation process sequence may be performed. Singulation is the moment when a structure, such as the first semiconductor structure 100 is section into multiple components, such as multiple semiconductor chip and/or die. In accordance with some embodiments, the first package components 40 are singulated from the first semiconductor structure 100 using any suitable dicing process as mechanical sawing or plasma dicing. In some embodiments, to facilitate the singulation process one or more carrier substrates may be employed. The portion of the first package component 40 removed by the singulation process is identified by reference number 600. It is noted that although a single remaining portion of the first package components 40 is depicted in FIG. 11, the present disclosure is not limited to only this example. The singulation process may be employed to provide any number of multiple first package components 40.

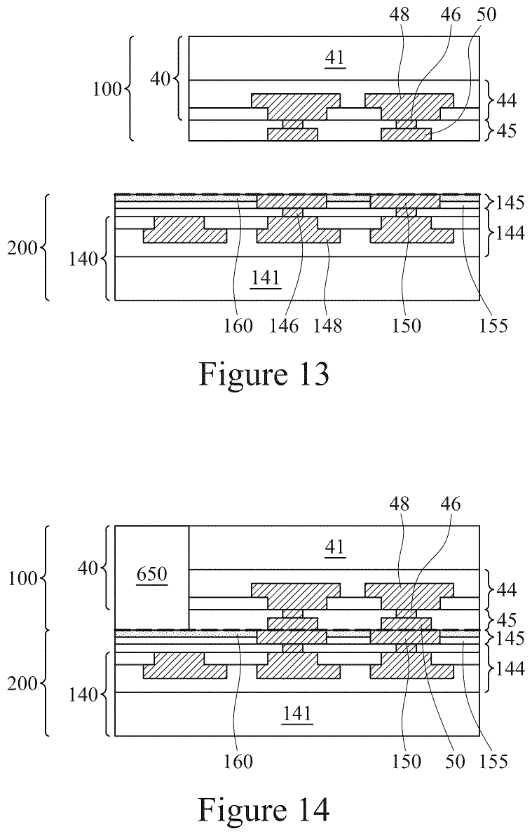

FIG. 12 illustrates an embodiment of a method that includes forming a second semiconductor structure 200 including a second plurality of metal lines 148 in a plurality of second dielectric layers 144 over a second substrate 141, wherein a second upper layer of the plurality of second dielectric layers 144 includes an organic bonding layer 160 and a second bonding pad 150. In some embodiments, the organic bonding layer 160 may be a polymeric bonding layer. In some embodiments, the organic bonding layer 160 may include carbon in amounts ranging from 40 wt. % to 90 wt. %. For example, the organic bonding layer 160 may include epoxy resins, polyimides, acrylics, silicones, benzocyclobutene (BCB), polymethylmethacrylate (PMMA), polystyrene (PS), or combinations thereof. In some embodiments, the thickness of the organic bonding layer 160 is less than the thickness of the second bonding pads 150. For example, the organic bonding layer 160 can have a thickness that is less than 1/2 the thickness of the second bonding pad 150, which may be a copper bonding pad. In some embodiments, the aforementioned conditions for the thickness for the organic bonding layer 160 can facilitate copper to copper bonding, as described below with reference to FIGS. 13 and 14.

Referring to FIG. 12, in some embodiments, the organic bonding layer 160 is separated from the plurality of second dielectric layers 144 by an intermediate inorganic bonding layer 155. The intermediate inorganic bonding layer 155 may be a silicon containing bonding layer. For example, the intermediate inorganic bonding layer 155 may include silicon oxide (SiOₓ), phospho-silicate glass (PSG), borosilicate glass (BSG), boron-doped phospho silicate glass (BPSG), fluorine-doped silicate glass (FSG), silicon nitride (SiₓN_{y}), silicon oxynitride (SiON), silicon oxycarbide (SiOC), silicon carbonitride (SiCN), or combinations thereof. In some embodiments, the thickness of the intermediate inorganic bonding layer 155 may provide that the intermediate of the second bonding pad 150 is coplanar with the intermediate of the intermediate inorganic bonding layer 155. As noted above, the organic bonding layer 160 and the intermediate inorganic bonding layer 155, as well as the other elements having references numbers illustrated in FIG. 12 have been described above with reference to FIGS. 1-6B.

FIG. 13 illustrates an embodiment of flipping the first semiconductor structure 100 depicted FIG. 11 to provide that the inorganic bonding layer 55 faces and is aligned with the organic bonding layer 160 of the second semiconductor structure 200 depicted in FIG. 12. In accordance with some embodiments, the bonding of first semiconductor structure 100 to the second semiconductor structure 200 includes pre-treating the inorganic bonding layer 55 and the organic bonding layer 160 in a pre-bonding process. In some embodiments, the pre-bonding process can include a plasma and/or wet-clean processes that can form hydroxyl groups on at least the inorganic bonding layer 55, which can help to join inorganic bonding layer 55 and organic bonding layer 160. The pre-treatment may further include performing an annealing process following the pre-bonding process. Further details for the pretreatment (including the plasma process) are provided above with reference to FIG. 3.

FIG. 14 illustrates an embodiment of contacting the inorganic bonding layer 55 to the organic bonding layer 160, and bonding the first semiconductor structure 100 to the second semiconductor structure 200, wherein the inorganic bonding layer 55 is bonded to the organic bonding layer 160. In some embodiments, bonding is effectuated by an annealing process. In some embodiments, during annealing, chemical bonds, such as silicon to oxygen (Si—O) bonds and/or silicon to nitrogen (Si—N), may be formed between the inorganic bonding layers 55 and the organic bonding layers 160, so that the inorganic bonding layers 55 and organic bonding layers 160 are bonded to each other with high bonding strength. In some embodiments, during the bonding and annealing processes, the temperature is raised above the glass transition temperature (Tg) of the polymer material of the organic bonding layer 160 to make it become softer and more able to absorb particle defects 501 and surface roughness 502 at the bond interface 500 in a manner that avoids void formation. The bonding process also bonds the first bonding pads 50 to the second bonding pads 150, which can result in a copper to copper bond. Further details for the bonding processes (including the annealing process) are provided above with reference to FIG. 4.

FIG. 14 further illustrates forming the gap fill 650. In some embodiments, the gap fill 650 may include a liner layer and a fill material that are formed on at least the first package components 40. In some embodiments, the liner layer may be a conformal layer extending along the top surfaces and the sidewalls of first package components and along top surfaces of organic bonding layer 160. In some embodiments, the liner layer may be formed of a dielectric material that has good adhesion to the sidewalls of first package components 40. For example, liner layer may be formed of an extra low-k (ELK) material, including a nitride such as silicon nitride and/or an oxide such as silicon oxide. The deposition of liner layer may include a conformal deposition process such as ALD, CVD, or any suitable process. In some embodiments, the fill material may be formed of a molding compound, an epoxy, a resin, and/or the like. For example, the fill material may comprise a nitride such as silicon nitride and/or an oxide such as silicon oxide and may be deposited using spin coating, FCVD, PECVD, LPCVD, ALD, or any suitable process. A planarization process such as a CMP process and/or a mechanical grinding process is then performed to remove portions of liner layer and filling material that extend over the illustrated top surface of first package components 40.

The process described above with reference to FIGS. 11-14 is a bonding process that is consistent with the methods and structures that are described in FIGS. 1-6B. The singulation process flow and use of the gap fill 650 that is illustrated in FIGS. 11-14 is equally applicable to bonding methods that include bonding levels 45′, 145′ including inorganic bonding layers 55 and organic bonding layers 160 to substantially eliminate voids as the bond interface, as described with reference to FIGS. 7-10. To apply the singulation process flow to a bonding process that does not include metal-to-metal bonding, the singulation process may be applied to the first semiconductor structure 100 that is depicted in FIG. 7. The sectioned first semiconductor structure may then be processed using the fusion bonding steps described with reference to FIGS. 8, 9 and 10. Following bonding of the sectioned first semiconductor structure 100 that was formed by the singulation process to a second semiconductor structure 200 through a bonded interface including the inorganic bonding layer 55 bonded to the organic bonding layer 160, a gap fill 650 may be applied to encapsulate the first semiconductor structure 100. The description of forming the gap fill that is described above with reference to FIG. 10 is equally applicable to a bonding process flow as described with reference to FIGS. 11-14.

It is further noted that in each of the embodiments described with reference to FIGS. 1-14, the first semiconductor structure 100, which can function as a top die, includes the inorganic bonding layer 55, and the second semiconductor structure 200, which can function as the bottom die (or substrate/carrier substrate) includes the organic bonding layer 160. The methods and structures of the present disclosure are not limited to only these examples. For example, in some embodiments, the first semiconductor structure 100 may be processed to provide the organic bonding layer 160, and the second semiconductor structure 200 may be processed to provide the inorganic bonding layer 55. This is applicable to the bonding as described with reference to FIGS. 1-4; the bonding process, as described with reference to FIGS. 7-10; and the bonding processes employing the singulation process flows and gap fill materials, as described with reference to FIGS. 11-14.

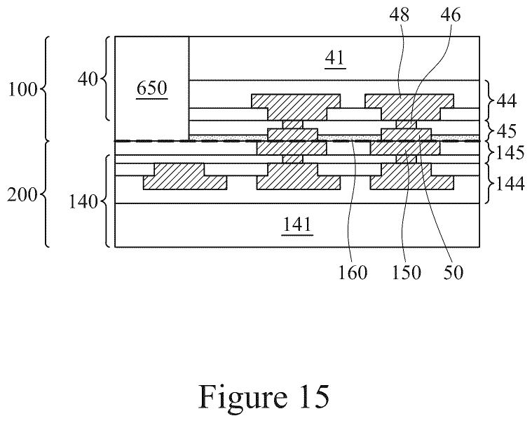

FIG. 15 illustrates an embodiment of an electronics package that was formed using a hybrid dielectric bonding method, in which an organic bonding layer 160 is integrated into the top side of the package. In an embodiment, the semiconductor package can include a first semiconductor structure 100 including a die substrate (first substrate 41) over a first plurality of metal lines 48 in the plurality of first dielectric layers 44. The first semiconductor structure 100 can also include a first bonding level 45 that includes an organic bonding layer 160 and a first bonding pad 50. In some embodiments, the semiconductor package can further include a second semiconductor structure 200 including a second plurality of metal lines 148 in a plurality of second dielectric layers 144 over a packaging substrate (second substrate 141). The second semiconductor structure 200 can include a second bonding level 145 that includes an organic bonding layer 160 and a second bonding pad 150, wherein the first semiconductor structure 100 is bonded to the second semiconductor structure 200 through an interface between the organic bonding layer 160 and the inorganic bonding layer 55. The first bonding pad 50 is also bonded to the second bonding pad 150. In some embodiments, the organic bonding layer 160 has a thickness than is less than 1/2 a thickness of the first bonding pad 50. In some embodiments, the die substrate (first substrate 41) provides the die components for a chiplet on support substrate packaging structure.

In some embodiments, the methods and structures of the present disclosure can provide bonding methods that employ an organic bonding layer to avoid the formation of voids that can result from particulates and/or surface roughness that can be present at the bond interface.

In an embodiment, a method comprising: forming a first semiconductor structure including a first plurality of metal lines in a first dielectric stack over a first substrate, wherein the first dielectric stack includes an inorganic bonding layer and a first metal containing contact pad connected to the first plurality of metal lines; forming a second semiconductor structure including a second plurality of metal lines in a second dielectric stack over a second substrate, wherein the second dielectric stack includes an organic bonding layer and a second metal containing contact pad; contacting the inorganic bonding layer to the organic bonding layer with the first metal containing contact pad aligned to the second metal containing contact pad; and bonding the first semiconductor structure to the second semiconductor structure, wherein the inorganic bonding layer is bonded to the organic bonding layer and the first metal containing contact pad is bonded to the second metal containing contact pad. In an embodiment, the organic bonding layer has a thickness than is less than ½ a thickness of the second metal containing contact pad. In an embodiment, the inorganic bonding layer comprises silicon oxide (SiOₓ), phospho-silicate glass (PSG), borosilicate glass (BSG), boron-doped phospho silicate glass (BPSG), fluorine-doped silicate glass (FSG), silicon nitride (SiₓN_{y}), silicon oxynitride (SiON), silicon oxycarbide (SiOC), silicon carbonitride (SiCN), or combinations thereof. In an embodiment, the organic bonding layer comprises carbon in amounts ranging from 40 wt. % to 90 wt. %. In an embodiment, the organic bonding layer comprises epoxy resins, polyimides, acrylics, silicones, benzocyclobutene (BCB), polymethylmethacrylate (PMMA), polystyrene (PS), or combinations thereof. In an embodiment, the inorganic bonding layer has a thickness that is greater than a thickness of the first copper containing contact pad. In an embodiment, the second dielectric stack is separated from the organic bonding layer by an intermediate silicon containing bonding layer.

In another embodiment, a method comprising: forming a first semiconductor structure including a first plurality of metal lines in a first dielectric stack over a first substrate, wherein a first upper layer of the first dielectric stack includes a silicon containing bonding layer and a first contact pad to the first plurality of metal lines; forming a second semiconductor structure including a second plurality of metal lines in a second dielectric stack over a second substrate, wherein a second upper layer of the second dielectric stack includes a polymeric bonding layer and a second contact pad, and the polymeric bonding layer has a thickness than is less than half a thickness of the second contact pad; contacting the first upper layer to the second upper layer with the first contact pad aligned to the second contact pad; and bonding the first semiconductor structure to the second semiconductor structure, wherein the silicon containing bonding layer is bonded to the polymeric bonding layer and the first contact pad is bonded to the second contact pad. In an embodiment, the method includes at least one of the first semiconductor structure and the second semiconductor structure is a chiplet on supporting substrate. In an embodiment, the bonding the first semiconductor structure to the second semiconductor structure comprises annealing to a temperature greater than a glass transition (Tg) temperature of the polymeric bonding layer. In an embodiment, the silicon containing bonding layer has a thickness that is greater than a thickness of the first contact pad. In an embodiment, the second plurality of metal lines in the second dielectric stack is separated from the polymeric bonding layer by an intermediate inorganic bonding layer.

In yet another embodiment, a semiconductor package comprising: a first semiconductor structure including a die substrate over a first plurality of metal lines in a first dielectric stack, the first dielectric stack including a first bonding pad in an inorganic bonding layer and electrically connected to the first plurality of metal lines; and a second semiconductor structure including a second plurality of metal lines in a second dielectric stack over a packaging substrate, the second semiconductor structure including a second bonding pad in an organic bonding layer and electrically connected to the second plurality of metal lines, wherein the first semiconductor structure is bonded to the second semiconductor structure through dielectric-to-dielectric bonding between the inorganic bonding layer and the organic bonding layer and through metal-to-metal bonding between the first bonding pad and second bonding pad. In an embodiment, the organic bonding layer is in the first semiconductor structure. In an embodiment, the organic bonding layer is in the second semiconductor structure. In an embodiment, during the annealing to the temperature greater than the glass temperature of the polymeric bonding layer, a copper to copper bond is formed between the first contact pad and the second contact pad. In an embodiment, the inorganic bonding layer comprises silicon oxide (SiOₓ), phospho-silicate glass (PSG), borosilicate glass (BSG), boron-doped phospho silicate glass (BPSG), fluorine-doped silicate glass (FSG), silicon nitride (SiₓN_{y}), silicon oxynitride (SiON), silicon oxycarbide (SiOC), silicon carbonitride (SiCN), or combinations thereof. In an embodiment, the organic bonding layer comprises epoxy resins, polyimides, acrylics, silicones, benzocyclobutene (BCB), polymethylmethacrylate (PMMA), polystyrene (PS), or combinations thereof. In an embodiment, the organic bonding layer comprises carbon in amounts ranging from 40 wt. % to 90 wt. %. In an embodiment, the second dielectric stack is separated from the organic bonding layer by a silicon containing bonding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor structure including a first plurality of metal lines in a first dielectric stack over a first substrate wherein the first dielectric stack includes an inorganic bonding layer and a first metal containing contact pad connected to the first plurality of metal lines;
forming a second semiconductor structure including a second plurality of metal lines in a second dielectric stack over a second substrate, wherein the second dielectric stack includes an organic bonding layer and a second metal containing contact pad;
contacting the inorganic bonding layer to the organic bonding layer with the first metal containing contact pad aligned to the second metal containing contact pad; and
bonding the first semiconductor structure to the second semiconductor structure, wherein the inorganic bonding layer is bonded to the organic bonding layer and the first metal containing contact pad is bonded to the second metal containing contact pad.

2. The method of claim 1, wherein organic bonding layer has a thickness that is less than ½ a thickness of the second metal containing contact pad.

3. The method of claim 1, wherein the inorganic bonding layer comprises silicon oxide (SiOx), phospho-silicate glass (PSG), borosilicate glass (BSG), boron-doped phospho silicate glass (BPSG), fluorine-doped silicate glass (FSG), silicon nitride (SixNy), silicon oxynitride (SiON), silicon oxycarbide (SiOC), silicon carbonitride (SiCN), or combinations thereof.

4. The method of claim 1, wherein the organic bonding layer comprises carbon in amounts ranging from 40 wt. % to 90 wt. %.

5. The method of claim 1, wherein the organic bonding layer comprises epoxy resins, polyimides, acrylics, silicones, benzocyclobutene (BCB), polymethylmethacrylate (PMMA), polystyrene (PS), or combinations thereof.

6. The method of claim 1, wherein the inorganic bonding layer has a thickness that is greater than a thickness of the first copper containing contact pad.

7. The method of claim 1, wherein the second dielectric stack is separated from the organic bonding layer by an intermediate silicon containing bonding layer.

8. A method comprising:
forming a first semiconductor structure including a first plurality of metal lines in a first dielectric stack over a first substrate, wherein a first upper layer of the first dielectric stack includes a silicon containing bonding layer and a first contact pad connected to the first plurality of metal lines;
forming a second semiconductor structure including a second plurality of metal lines in a second dielectric stack over a second substrate, wherein a second upper layer of the second dielectric stack includes a polymeric bonding layer and a second contact pad, and the polymeric bonding layer has a thickness that is less than half a thickness of the second contact pad;
contacting the first upper layer to the second upper layer with the first contact pad aligned to the second contact pad; and
bonding the first semiconductor structure to the second semiconductor structure, wherein the silicon containing bonding layer is bonded to the polymeric bonding layer and the first contact pad is bonded to the second contact pad.

9. The method of claim 8, wherein at least one of the first semiconductor structure and the second semiconductor structure is a chiplet on supporting substrate.

10. The method of claim 8, wherein the bonding the first semiconductor structure to the second semiconductor structure comprises annealing to a temperature greater than a glass transition temperature (Tg) of the polymeric bonding layer.

11. The method of claim 10, wherein the during the annealing to the temperature greater than the glass temperature of the polymeric bonding layer, a copper to copper bond is formed between the first contact pad and the second contact pad.

12. The method of claim 8, wherein the second plurality of metal lines in the second dielectric stack is separated from the polymeric bonding layer by an intermediate inorganic bonding layer.

13. A semiconductor package comprising:
a first semiconductor structure including a die substrate over a first plurality of metal lines in a first dielectric stack, the first dielectric stack including a first bonding pad in an inorganic bonding layer and electrically connected to the first plurality of metal lines; and
a second semiconductor structure including a second plurality of metal lines in a second dielectric stack over a packaging substrate, the second semiconductor structure including a second bonding pad in an organic bonding layer and electrically connected to the second plurality of metal lines, wherein the first semiconductor structure is bonded to the second semiconductor structure through dielectric-to-dielectric bonding between the inorganic bonding layer and the organic bonding layer and through metal-to-metal bonding between the first bonding pad and second bonding pad.

14. The semiconductor package of claim 13, wherein the organic bonding layer is in the first semiconductor structure.

15. The semiconductor package of claim 13, wherein the organic bonding layer is in the second semiconductor structure.

16. The semiconductor package of claim 13, wherein the organic bonding layer has a thickness than is less than 1/2 a thickness of the second bonding pad.

17. The semiconductor package claim 13, wherein the inorganic bonding layer comprises silicon oxide (SiOₓ), phospho-silicate glass (PSG), borosilicate glass (BSG), boron-doped phospho silicate glass (BPSG), fluorine-doped silicate glass (FSG), silicon nitride (SiₓN_{y}), silicon oxynitride (SiON), silicon oxycarbide (SiOC), silicon carbonitride (SiCN), or combinations thereof.

18. The semiconductor package of claim 13, wherein the organic bonding layer comprises epoxy resins, polyimides, acrylics, silicones, benzocyclobutene (BCB), polymethylmethacrylate (PMMA), polystyrene (PS), or combinations thereof.

19. The semiconductor package of claim 13, wherein the organic bonding layer comprises carbon in amounts ranging from 40 wt. % to 90 wt. %.

20. The semiconductor package of claim 13, wherein the second dielectric stack is separated from the organic bonding layer by a silicon containing bonding layer.
